(19) United States
(12) Patent Application Publication
(10) Pub. No.: US 2026/0213710 A1
(43) Pub. Date: Jul. 23, 2026

(54) Oscillator circuit having voltage-withstanding mechanism

(71) Applicant: Realtek Semiconductor Corporation, Hsinchu (TW)

(72) Inventor: YUNG-CHUNG CHEN, Hsinchu (TW)

(21) Appl. No.: 19/388,396

(22) Filed: Nov. 13, 2025

(30) Foreign Application Priority Data
Nov. 15, 2024 (TW) 113144150

(51) Int. Cl. H03B 5/12

(52) U.S. Cl. CPC H03B 5/1212; H03B 5/1228; H03B 5/1265; H03B 2200/009

(57) ABSTRACT

An oscillator circuit having a voltage-withstanding mechanism is provided that includes a first inductor circuit, a cross-coupled transistor circuit, a second inductor circuit and a capacitor circuit. The first inductor circuit is electrically coupled to a pair of connection terminals. The cross-coupled transistor circuit is electrically coupled to the pair of connection terminals. The second inductor circuit is electrically coupled between the pair of connection terminals and a pair of oscillating output terminals. The capacitor circuit is electrically coupled between the pair of oscillating output terminals.

### BACKGROUND OF THE INVENTION

### 1. Field of the Invention

The present invention relates to an oscillator circuit having a voltage-withstanding mechanism.

### 2. Description of Related Art

An oscillator circuit, especially an inductor-capacitor (LC) oscillator circuit, is a circuit including a capacitor circuit and an inductor circuit electrically coupled to each other and operates according to the oscillating effect. The oscillator circuit is widely used in circuits such as, but not limited to oscillators, filters, tuners and mixers.

When the voltage swing of an output signal of the oscillator circuit is larger, a phase noise is smaller. However, the larger voltage swing may cause damage to internal circuit components of the oscillator circuit when the voltage-withstanding range of these components is not large enough. Once the voltage swing is lowered in order not to damage the circuit components, the phase noise may increase. The requirements of low phase noise and the prevention of the exceeding the voltage-withstanding range of the circuit components are difficult to simultaneously be accomplished in the circuit design.

### SUMMARY OF THE INVENTION

In consideration of the problem of the prior art, an object of the present invention is to supply an oscillator circuit having a voltage-withstanding mechanism.

The present invention discloses an oscillator circuit having a voltage-withstanding mechanism that includes a first inductor circuit, a cross-coupled transistor circuit, a second inductor circuit and a capacitor circuit. The first inductor circuit is electrically coupled to a pair of connection terminals. The cross-coupled transistor circuit is electrically coupled to the pair of connection terminals. The second inductor circuit is electrically coupled between the pair of connection terminals and a pair of oscillating output terminals. The capacitor circuit is electrically coupled between the pair of oscillating output terminals.

These and other objectives of the present invention will no doubt become obvious to those of ordinary skill in the art behind reading the following detailed description of the preferred embodiments that are illustrated in the various figures and drawings.

### BRIEF DESCRIPTION OF THE DRAWINGS

FIG. 1 illustrates a circuit diagram of an oscillator circuit having a voltage-withstanding mechanism according to an embodiment of the present invention.

FIG. 2 illustrates a layout diagram of the oscillator circuit according to an embodiment of the present invention.

FIG. 3 illustrates a waveform diagram of the waveforms of the first voltage and the second voltage according to an embodiment of the present invention.

### DETAILED DESCRIPTION OF THE PREFERRED EMBODIMENTS

An aspect of the present invention is to provide an oscillator circuit having a voltage-withstanding mechanism to prevent transistors in a cross-coupled transistor circuit from operating under a voltage exceeding a voltage-withstanding range thereof when connection terminals are operated under a smaller voltage swing, and lower a phase noise of oscillating output terminals when the connection terminals are operated under a larger voltage swing.

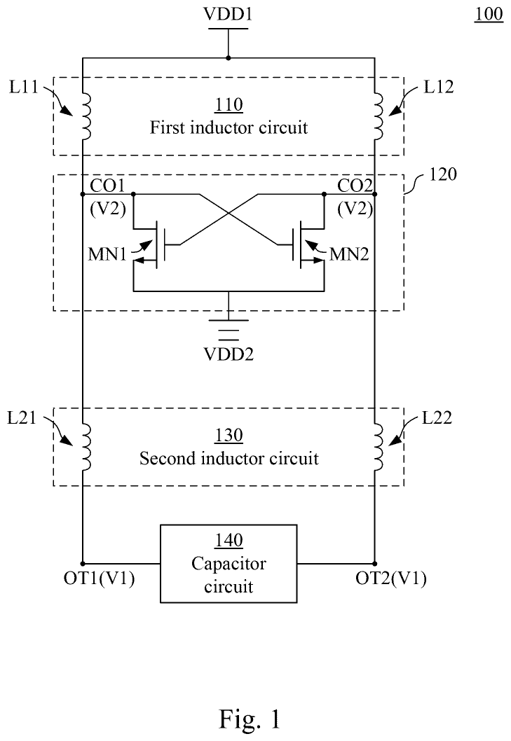

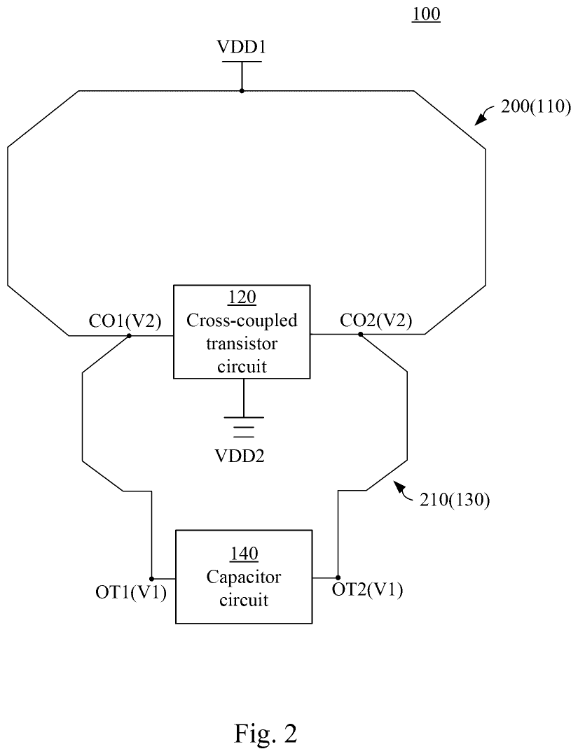

Reference is now made to FIG. 1 and FIG. 2 at the same time. FIG. 1 illustrates a circuit diagram of an oscillator circuit 100 having a voltage-withstanding mechanism according to an embodiment of the present invention. FIG. 2 illustrates a layout diagram of the oscillator circuit 100 according to an embodiment of the present invention.

The oscillator circuit 100 includes a first inductor circuit 110, a cross-coupled transistor circuit 120, a second inductor circuit 130 and a capacitor circuit 140.

The first inductor circuit 110 is electrically coupled between a pair of connection terminals CO1 and CO2. In FIG. 1, the first inductor circuit 110 is illustrated to include an inductor L11 electrically coupled between a first power voltage VDD1 and the connection terminal CO1 and an inductor L12 electrically coupled between the first power voltage VDD1 and the connection terminal CO2.

In practical implementation, the first inductor circuit 110 may be implemented by a first inductor coil 200 illustrated in FIG. 2 to be equivalent to the inductor L11 and the inductor L12 in FIG. 1. A pair of terminals of such a first inductor coil 200 are electrically coupled to the connection terminals CO1 and CO2. The first inductor coil 200 can further be electrically coupled to the first power voltage VDD1 through a central tap 210 included thereby.

The cross-coupled transistor circuit 120 is electrically coupled between the connection terminals CO1 and CO2 and a second power voltage VDD2.

As illustrated FIG. 1, in the present embodiment, the cross-coupled transistor circuit 120 includes a first transistor MN1 and a second transistor MN2. In FIG. 2, the cross-coupled transistor circuit 120 is illustrated as a simplified block.

The first transistor MN1 has two first source/drain terminals respectively electrically coupled to a first connection terminal of the connection terminals CO1 and CO2 (e.g., the connection terminal CO1) and the second power voltage VDD2. The second transistor MN2 has two second source/drain terminals respectively electrically coupled to a second connection terminal of the connection terminals CO1 and CO2 (e.g., the connection terminal CO2) and the second power voltage VDD2. A first gate terminal of the first transistor MN1 is electrically coupled to the second connection terminal (e.g., the connection terminal CO2), and a second gate terminal of the second transistor MN2 is electrically coupled to the first connection terminal (e.g., the connection terminal CO1).

In the embodiment in FIG. 1, each of the first transistor MN1 and the second transistor MN2 is an N-type transistor.

The second inductor circuit 130 is electrically coupled between the connection terminals CO1 and CO2 and a pair of oscillating output terminals OT1 and OT2. In FIG. 1, the second inductor circuit 130 is illustrated to include an inductor L21 electrically coupled between the connection terminal CO1 and the oscillating output terminal OT1 and an inductor L22 electrically coupled between the connection terminal CO2 and the oscillating output terminal OT2.

In practical implementation, the second inductor circuit 130 may be implemented by a second inductor coil 220 illustrated in FIG. 2 to be equivalent to the inductor L21 and the inductor L22 in FIG. 1. A pair of first terminals of such a second inductor coil 220 are electrically coupled to the connection terminals CO1 and CO2, and a pair of second terminals of the second inductor coil 220 are electrically coupled to the oscillating output terminals OT1 and OT2.

In an embodiment, a first area of the first inductor circuit 110 is larger than a second area of the second inductor circuit 130. In an embodiment, a first inductance of the first inductor circuit 110 is larger than a second inductance of the second inductor circuit 130.

The capacitor circuit 140 is electrically coupled between the oscillating output terminals OT1 and OT2. In FIG. 1 and FIG. 2, the capacitor circuit 140 is illustrated as a simplified block. However, in an embodiment, the capacitor circuit 140 may be a switch capacitor array or a plurality of voltage-controlled capacitors (not illustrated in the figure), and may selectively include an output buffer circuit (not illustrated in the figure). In another embodiment, the capacitor circuit 140 includes at least one metal-oxide-metal capacitor (MOMCAP).

By using the configuration described above, the oscillator circuit 100 may operate according to the voltage difference between the first power voltage VDD1 and the second power voltage VDD2, wherein the first power voltage VDD1 can be such as, but not limited to a positive voltage and the second power voltage VDD2 can be such as, but not limited to a ground voltage. When the oscillator circuit 100 operates, the oscillating output terminals OT1 and OT2 respectively have a first voltage V1 and the connection terminals CO1 and CO2 respectively have a second voltage V2. A first largest swing SW1 of the first voltage V1 is larger than a second largest swing SW2 of the second voltage V2.

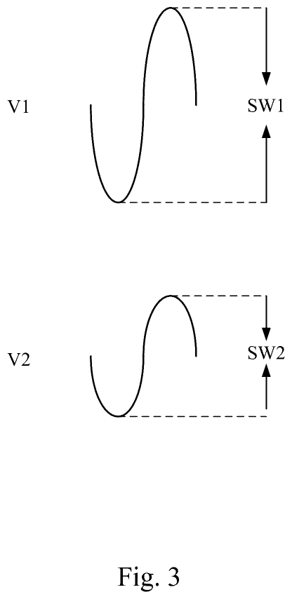

Reference is now made to FIG. 3 at the same time. FIG. 3 illustrates a waveform diagram of the waveforms of the first voltage V1 and the second voltage V2 according to an embodiment of the present invention.

In an embodiment, the first inductor circuit 110 has a first inductance L1, the second inductor circuit 130 has a second inductance L2.

The relation between the second largest swing SW2 of the second voltage V2 and the first largest swing SW1 of the first voltage V1 is related to the ratio between the inductances such that the first largest swing SW1 is larger than the second largest swing SW2. The relation between the second largest swing SW2 and the first largest swing SW1 is expressed by the following equation:

$$SW 2 = SW 1 \times L 1 / ( L 1 + L 2 ) \qquad ( equation 1 )$$

Based on the configuration described above, the oscillator circuit of the present invention prevents the transistors in the cross-coupled transistor circuit from operating under the voltage exceeding the voltage-withstanding range thereof when the connection terminals are operated under the smaller voltage swing, and lowers the phase noise of the oscillating output terminals when the connection terminals are operated under the larger voltage swing.

It is appreciated that the embodiments described above are merely an example. In other embodiments, it should be appreciated that many modifications and changes may be made by those of ordinary skill in the art without departing, from the spirit of the disclosure.

For example, the above embodiments are described based on the condition that each of the first transistor and the second transistor included in the cross-coupled transistor circuit is the N-type transistor. In other embodiments, when connection relation between the oscillator circuit 100 and power voltages including the first power voltage and the second power voltage are adjusted and the voltage levels of the first power voltage and the second power voltage are adjusted as well, each of the first transistor and the second transistor included in the cross-coupled transistor circuit can be a P-type transistor or the first transistor and the second transistor can be a pair of complementary metal-oxide-semiconductor (CMOS) transistors. The present invention is not limited thereto. When the cross-coupled transistor circuit is implemented by complementary metal-oxide-semiconductor transistors, the first inductor coil 200 illustrated in FIG. 2 does not include the central tap 210 and does not need to receive the first power voltage VDD1.

Moreover, the shape of the inductor coil illustrated in FIG. 2 is merely an example. In other embodiments, the inductor coil may be implemented by using other shapes under the condition that the inductor coil and the capacitor circuit together form an oscillating structure. The shape of the inductor coil is not limited by the shape illustrated in FIG. 2.

In summary, the present invention discloses the oscillator circuit having a voltage-withstanding mechanism to prevent transistors in a cross-coupled transistor circuit from operating under a voltage exceeding a voltage-withstanding range thereof when connection terminals are operated under a smaller voltage swing, and lower a phase noise of oscillating output terminals when the connection terminals are operated under a larger voltage swing.

The aforementioned descriptions represent merely the preferred embodiment of the present invention, without any intention to limit the scope of the present invention thereto. Various equivalent changes, alterations, or modifications based on the claims of present invention are all consequently viewed as being embraced by the scope of the present invention.

What is claimed is:

1. An oscillator circuit having a voltage-withstanding mechanism, comprising:
a first inductor circuit electrically coupled to a pair of connection terminals;
a cross-coupled transistor circuit electrically coupled to the pair of connection terminals;
a second inductor circuit electrically coupled between the pair of connection terminals and a pair of oscillating output terminals; and
a capacitor circuit electrically coupled between the pair of oscillating output terminals.

2. The oscillator circuit of claim 1, wherein the cross-coupled transistor circuit comprises:
a first transistor having two first source/drain terminals respectively electrically coupled to a first connection terminal of the pair of connection terminals and a power voltage; and
a second transistor having two second source/drain terminals respectively electrically coupled to a second connection terminal of the pair of connection terminals and the power voltage;
wherein a first gate terminal of the first transistor is electrically coupled to the second connection terminal, and a second gate terminal of the second transistor is electrically coupled to the first connection terminal.

3. The oscillator circuit of claim 1, wherein the first transistor is a P-type transistor or an N-type transistor.

4. The oscillator circuit of claim 1, wherein the cross-coupled transistor circuit comprises a pair of complementary metal-oxide-semiconductor (CMOS) transistor.

5. The oscillator circuit of claim 1, wherein the first inductor circuit is a first inductor coil, and a pair of terminals of the first inductor coil are electrically coupled to the pair of connection terminals.

6. The oscillator circuit of claim 1, wherein the second inductor circuit is a second inductor coil, wherein a pair of first terminals of the second inductor coil are electrically coupled to the pair of connection terminals and a pair of second terminals of the second inductor coil are electrically coupled to the pair of oscillating output terminals.

7. The oscillator circuit of claim 1, wherein the capacitor circuit comprises at least one metal-oxide-metal capacitor (MOMCAP).

8. The oscillator circuit of claim 1, wherein a first area of the first inductor circuit is larger than a second area of the second inductor circuit.

9. The oscillator circuit of claim 1, wherein a first inductance of the first inductor circuit is larger than a second inductance of the second inductor circuit.

10. The oscillator circuit of claim 1, wherein the capacitor circuit is a switch capacitor array or a plurality of voltage-controlled capacitors and selectively comprises an output buffer circuit.
